(19) United States
(12) Patent Application Publication
(10) Pub. No.: US 2003/0177065 A1
(43) Pub. Date: Sep. 18, 2003

(54) Promotional item for distribution with a commercial product

(76) Inventor: Gianfranco Raso, Monaco (MC)

Correspondence Address: ROTHWELL, FIGG, ERNST & MANBECK, P.C., 1425 K STREET, N.W., SUITE 800, WASHINGTON, DC, 20005, US

(21) Appl. No.: 10/332,269

(22) PCT Filed: Jul. 5, 2001
(86) PCT No.: PCT/EP01/07689

(51) Int. Cl. G06F 17/60

(52) U.S. Cl. 705/14

(57) ABSTRACT

The item (1) comprises an electronic chip (2; 2′) to be connected, by means of a connection device or interface (3, 5), to a widely-distributed electronic apparatus (6) which can use its contents. The chip (2, 2′) contains (first) information or data usable by a user by means of the apparatus (6) and may also contain further partial information or data that can be acquired permanently by the apparatus (6) and can be used only in combination with further partial information or data that can be acquired from at least one other, similar chip (2, 2′).

The subject of the present invention is a promotional item for distribution in association with a commercial product such as, for example, a food product, in order to promote sales thereof.

The practice of associating promotional items with commercial products is very widespread.

As is well known, the “attractiveness” of the promotional items depends on the target public for whom the commercial products are predominantly intended.

Thus, for example, in the field of food products intended predominantly for a juvenile or adolescent public, toys or similar items are used as promotional items and are often produced in numerous variants which can form a “collection”.

In recent times, the spread of mass-communication means and of electronic apparatus for communication, recreation, or work, such as personal computers, cellular telephones, etc. has increased at a bewildering pace. This has led to a considerable increase in interest in, knowledge of, and familiarity with the use of such means and apparatus, even at the level of the juvenile or adolescent public.

This new and overwhelming tendency in the interests of the younger members of the public represents a considerable sociological phenomenon which requires a reconsideration of current commercial practices and, in particular, also of the promotional items which are distributed in association with commercial products intended for this public.

An object of the present invention is to provide an innovative promotional item which takes account of these new trends in the interests of the public, particularly of the younger members of the public.

This and other objects are achieved, according to the invention, by a promotional item the basic characteristics of which are defined in appended claim 1.

Further characteristics and advantages of the invention will become clear from the following detailed description, given by way of non-limiting example, with reference to the appended drawings, in which:

FIG. 1 is a perspective view of an electronic chip which can be used as a promotional item according to the invention,

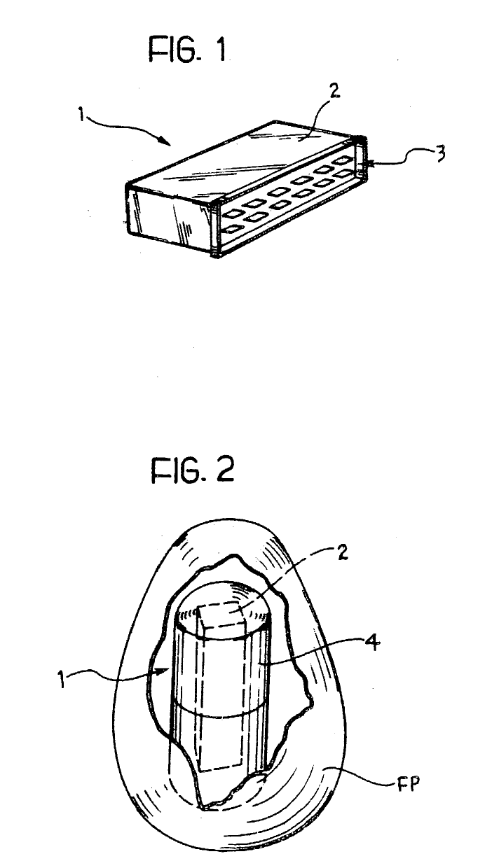

FIGS. 2 to 4 are perspective views which show commercial products, in particular food products, with which promotional items according to the invention are associated,

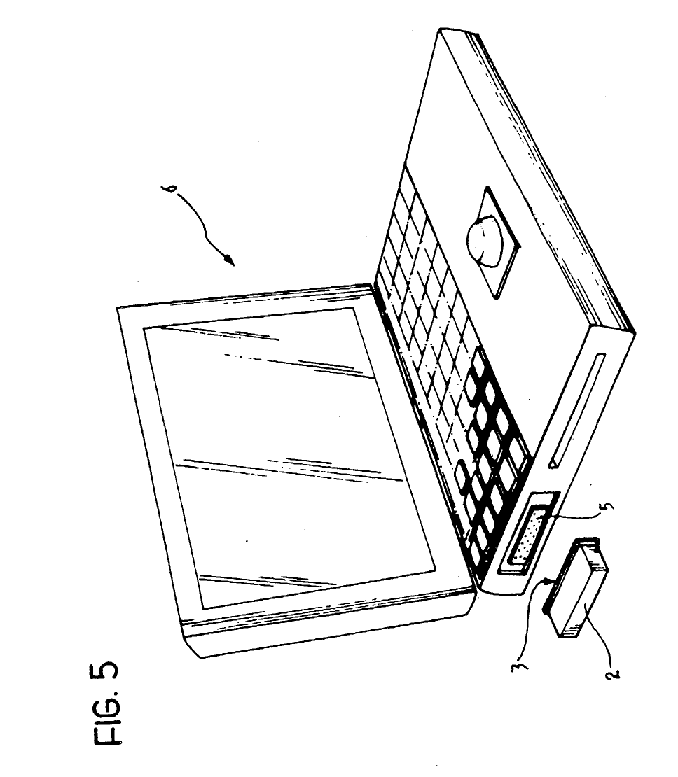

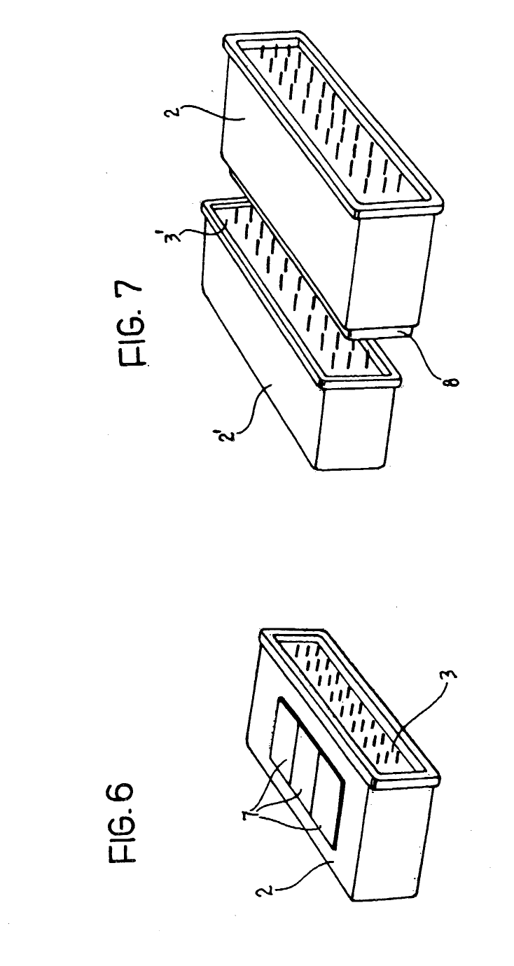

FIG. 5 is a perspective view of a portable personal computer in association with which a promotional item according to the invention can be used,

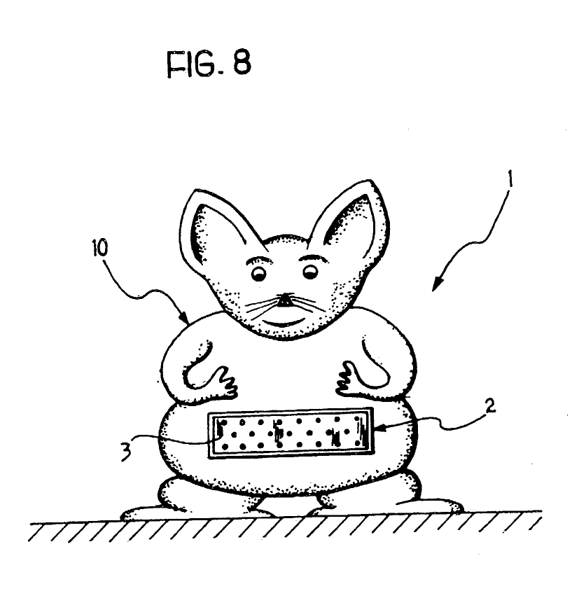

FIGS. 6 and 7 are two perspective views of promotional items according to the invention, and

FIG. 8 shows a promotional item according to the invention including a toy in which an electronic chip is incorporated.

In FIG. 1, a promotional item for distribution in association with a commercial product, in particular a food product, is indicated 1.

The promotional item 1 comprises an electronic chip containing a non-volatile memory 2 provided with a standard multi-pole connector.

FIG. 2 shows, by way of non-limiting example, a food product FP with which the promotional item 1 is associated. In the embodiment of FIG. 2, the food product FP is a chocolate egg which contains an electronic chip 2 of the type shown in FIG. 1, enclosed in a container or case 4. Incidentally, the container or case 4 shown in FIG. 2 is, for example, of the type described in International patent application WO93/00267.

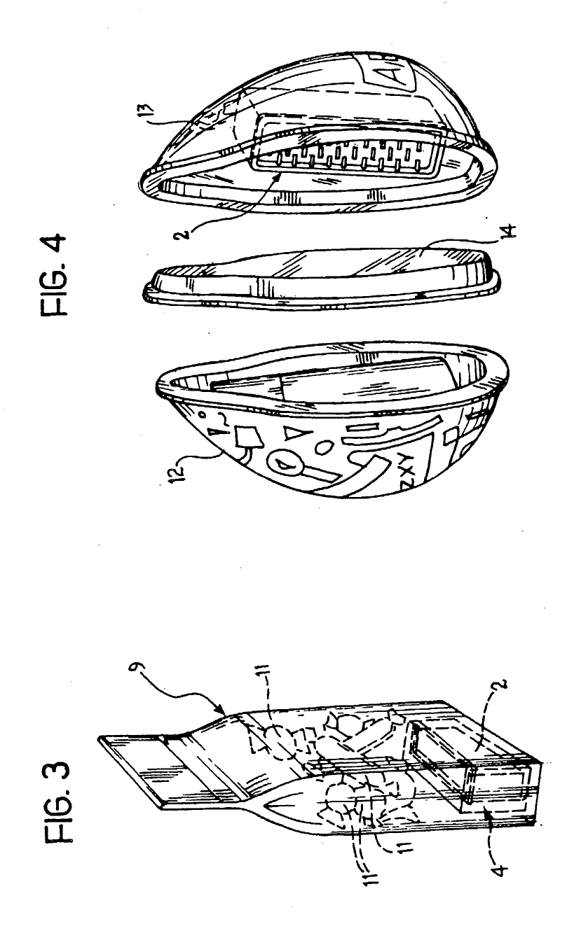

FIG. 3 shows, as a further example, a bag-like package 9 enclosing a plurality of sweets 11 (or similar food products) and an electronic chip 2, housed in a case 4, as a promotional item.

FIG. 4 shows a further example of a package comprising two half-shells or portions 12, 13 which can be coupled together with the interposition of a separating partition or dividing wall 14. One of the half-shells 12, is made, for example, of edible material (chocolate or the like). The receptacle defined between the partition 14 and the other half-shell 13, on the other hand, contains a promotional item represented by an electronic chip 2.

The promotional item according to the invention may be packaged and associated with a commercial product in many different ways. The commercial product or, in particular, the food product, with which the promotional item is associated may also be of widely varying types.

The electronic chip 2 is intended to be connected, by means of a standard connection device or interface, to a widely-distributed electronic apparatus which can use its contents.

In the embodiment shown in FIG. 5, the electronic chip 2 can be connected to an input/output port 5 of a personal computer 6. The port 5 is, for example, a parallel port normally intended for the connection of a printer to the personal computer.

The widely distributed electronic apparatus to which the electronic chip 2 is intended to be connected may, however, be, in general, any electronic apparatus provided with a microprocessor, for example, a cellular telephone, a television set, a so-called play station, a television decoder, etc.

The electronic chip used includes a predetermined information or data content.

In particular, the electronic chip 2 contains first information or data which can be used by a user, by means of the electronic apparatus. This first information or data may constitute, for example, a program for executing a video game or for presenting other audio-visual information, for example, instructive, cultural, or educational information.

In addition to the first information or data, the electronic chip 2 contains further information or data for enabling the first information or data to be used only when the chip is physically connected to the electronic apparatus the use of which is provided for. This characteristic prevents the usable content of the chip from being “downloaded” into memories of the electronic apparatus for subsequent use after the chip has been given away to a third party. The giving away of the chip to a third party in this way, after “downloading” its content, would greatly reduce or even cancel out the attractiveness of the promotional item.

The electronic chip 2 may advantageously but not necessarily contain additional information or data for at least partially cancelling the first information or data after a predetermined period of time or a predetermined event, subsequent to the first use of the chip.

According to a further aspect of the invention, the electronic chip 2 may also contain further partial information or data which can be acquired and retained permanently by the electronic apparatus to which the chip is connected but which can be used by the user solely in combination with further partial information or data that can be acquired from at least one other, similar chip. This solution enables the above-mentioned information or data, that is, the first information or data which can be used only when the chip is physically connected to the apparatus, to be used by the user immediately. Moreover, when the chip is connected to the electronic apparatus of use, the further partial information or data can be acquired and retained permanently in the apparatus of use for subsequent combination with the further partial information or data that can be acquired from one or more other, similar chips. With this solution, it is therefore possible, for example, to enable a user to use a video game of complex architecture, the program of which is broken up, as partial sets of information or data, in a plurality of chips. The collection of the various chips is thus encouraged and this translates into a further incentive for promoting sales of the commercial products with which the chips are associated.

According to a further aspect of the invention, the electronic chip 2 may contain information or data and/or decoding devices for decoding encrypted signals that can be acquired independently by the electronic apparatus for using the chip. By way of example, a chip of this type may contain data identifying a decoding polynomial for deciphering encrypted signals circulating on the Internet.

The chip 2 may also contain information or data for enabling the electronic apparatus to which the chip is connected to access a communication network such as the Internet. In particular, the chip 2 may contain information or data permitting access to a node or site on such a communication network to be accessed.

In general, the electronic chip 2 may be passive and arranged to receive electrical-supply energy from the electronic apparatus with which it is operatively associated.

Alternatively, the electronic chip 2 may be active, having independent electrical-energy supply means. In that case, the chip 2 may comprise, for example, one or more photo-voltaic cells such as those indicated 7 in FIG. 6 and/or may have, for example, a supply battery.

According to another variant shown in FIG. 7, in addition to the connector 3 for connection to an electronic apparatus of use, the electronic chip 2 may comprise, a further connector, indicated 8, for enabling it to be connected to a further electronic memory chip 2′. This further chip 2′ has a connector 3′ for connection to the connector 8 of the “master” chip 2.

The chip 2′ may advantageously contain partial information or data which can be used by the user in combination with partial information or data contained in the main chip 2.

With reference to FIG. 8, according to a further aspect of the invention, an electronic chip 2 of one of the types described above may advantageously be incorporated in a gadget, for example, a toy 10, in a manner such that its terminals are accessible in a portion of the surface of the gadget.

Naturally, the principle of the invention remaining the same, the forms of embodiment and details of construction may be varied widely with respect to those described and illustrated purely by way of non-limiting example, without thereby departing from the scope of the invention as defined in the appended claims.

1. A promotional item (1) for distribution in association with a commercial product (FP) such as a food product, in order to promote sales thereof,
comprising an electronic chip (2; 2′) which can be connected, by means of a connection device or interface (3, 5), to a widely-distributed electronic apparatus (6) which can use the contents of the chip,
the chip (2, 2′) containing (first) information or data which can be used by a user, by means of the apparatus (6).

2. An item according to the preceding claim in which the chip (2, 2′) also contains further partial information or data that can be acquired permanently by the apparatus (6) and can be used solely in combination with further partial information or data that can be acquired from at least one other, similar chip (2, 2′).

3. An item according to any one of the preceding claims in which the chip (2, 2′) can be connected to an interface (5) of a personal computer or other electronic apparatus (6) provided with a microprocessor, the interface being, for example, a parallel port normally intended for the connection of a printer to the personal computer or other electronic apparatus (6).

4. An item according to any one of the preceding claims in which the chip (2, 2′) contains information or data and/or decoding devices for decoding encrypted signals that can be acquired by the apparatus (6).

5. An item according to any one of the preceding claims in which the chip (2, 2′) contains information or data for enabling the apparatus (6) to access a communication network.

6. An item according to claim 5 in which the chip (2, 2′) contains information or data for enabling the apparatus (6) to access a node or site of a communication network.

7. An item according to any one of the preceding claims, in which the chip (2, 2′) contains further information or data for enabling the first information or data to be used only when the chip (2, 2′) is physically connected to the apparatus (6).

8. An item according to any one of the preceding claims in which the chip (2, 2′) further contains information or data for bringing about at least partial cancellation of the first information or data after a predetermined period of time or a predetermined event, subsequent to a use of the chip (2, 2′).

9. An item according to any one of the preceding claims in which the chip (2, 2′) is passive and is arranged to receive electrical-supply energy from the apparatus (6).

10. An item according to any one of claims 1 to 8 in which the chip (2, 2′) is active and is provided with independent electrical-energy supply means (7).

11. An item according to any one of the preceding claims in which the chip (2) has interconnection means (8) for enabling it to be connected to a further electronic-memory chip (2′).

12. An item according to any one of the preceding claims, further comprising a gadget such as a toy (10) in which the chip (2, 2′) is incorporated in a manner such that its terminals (3) are accessible on a portion of the surface of the gadget (10).
